(19) United States
(12) Patent Application Publication
(10) Pub. No.: US 2013/0255568 A1
(43) Pub. Date: Oct. 3, 2013

(54) METHOD FOR MANUFACTURING SILICON CARBIDE SINGLE CRYSTAL

(71) Applicant: SUMITOMO ELECTRIC INDUSTRIES, LTD., Osaka (JP)

(72) Inventors: Hiroki INOUE, Itami-shi (JP); Makoto SASAKI, Itami-shi (JP); Shin HARADA, Osaka-shi (JP); Eiryo TAKASUKA, Itami-shi (JP); Shinsuke FUJIWARA, Itami-shi (JP)

(73) Assignee: SUMITOMO ELECTRIC INDUSTRIES, LTD., Osaka (JP)

(21) Appl. No.: 13/780,127

(22) Filed: Feb. 28, 2013

Related U.S. Application Data
(60) Provisional application No. 61/618,951, filed on Apr. 2, 2012.

(30) Foreign Application Priority Data
Apr. 2, 2012 (JP) 2012-083613

(51) Int. Cl. C30B 23/06; C30B 23/02

(52) U.S. Cl. CPC C30B 23/066; C30B 23/025
USPC 117/106

(57) ABSTRACT

A method for manufacturing silicon carbide single crystal having a diameter larger than 100 mm by sublimation includes the following steps. A seed substrate made of silicon carbide and silicon carbide raw material are prepared. Silicon carbide single crystal is grown on the growth face of the seed substrate by sublimating the silicon carbide raw material. In the step of growing silicon carbide single crystal, the maximum growing rate of the silicon carbide single crystal growing on the growth face of the seed substrate is greater than the maximum growing rate of the silicon carbide crystal growing on the surface of the silicon carbide raw material. Thus, there can be provided a method for manufacturing silicon carbide single crystal allowing a thick silicon carbide single crystal film to be obtained, when silicon carbide single crystal having a diameter larger than 100 mm is grown.

### BACKGROUND OF THE INVENTION

1. Field of the Invention

The present invention relates to a method for manufacturing silicon carbide single crystal, more particularly, a method for manufacturing silicon carbide single crystal by sublimation.

2. Description of the Background Art

In recent years, silicon carbide substrates are now beginning to be used for manufacturing semiconductor devices. Silicon carbide has a bandgap greater than that of silicon. Therefore, a semiconductor device based on a silicon carbide substrate is advantageous in that the breakdown voltage is high, the on resistance is low, and degradation in the property under high-temperature environment is small.

As a method for manufacturing such a silicon carbide substrate, Japanese Patent Laying-Open Nos. 62-66000 and 5-58774 disclose the method for manufacturing a silicon carbide single crystal substrate by sublimation. According to the method thereof, silicon carbide raw material arranged in a crucible formed of carbon is sublimated at high temperature, causing recrystallization of sublimation gas on the seed substrate at the side opposite to where the silicon carbide raw material is arranged to form silicon carbide single crystal.

### SUMMARY OF THE INVENTION

However, when silicon carbide single crystal having a diameter larger than 100 mm is to be grown by the method of the aforementioned Japanese Patent Laying-Open Nos. 62-66000 and 5-58774, it was difficult to obtain a thick silicon carbide single crystal film.

The present invention is directed to solving the aforementioned problem. An object of the present invention is to provide a method for manufacturing silicon carbide single crystal allowing a thick silicon carbide single crystal film to be obtained when silicon carbide single crystal having a diameter larger than 100 mm is grown.

The inventors conducted diligent research into the cause of the difficulty in obtaining a thick silicon carbide single crystal film when silicon carbide single crystal having a diameter larger than 100 mm is grown. As a result, they found that, when the size of the silicon carbide single crystal increases, the growing rate of the silicon carbide single crystal on the growth face of the seed substrate becomes lower than the growing rate of the silicon carbide crystal on the surface of the silicon carbide raw material. The growth of the silicon carbide crystal on the surface of the silicon carbide raw material causes the space where the silicon carbide single crystal grows on the seed substrate to become smaller. Therefore, when silicon carbide single crystal having a diameter larger than 100 mm is grown, it was difficult to grow a thick silicon carbide single crystal film having a height greater than or equal to approximately 20 mm, for example, on the seed substrate.

A method for manufacturing silicon carbide crystal of the present invention is directed to manufacturing silicon carbide single crystal having a diameter larger than 100 mm by sublimation. The method includes the following steps. A seed substrate made of silicon carbide and silicon carbide raw material are prepared. Silicon carbide single crystal is grown on the growth face of the seed substrate by sublimating the silicon carbide raw material. In the step of growing silicon carbide single crystal, the maximum growing rate of the silicon carbide single crystal growing on the growth face of the seed substrate is greater than the maximum growing rate of the silicon carbide crystal growing on the surface of the silicon carbide raw material.

According to the method for manufacturing silicon carbide single crystal of the present invention, the maximum growing rate of the silicon carbide single crystal growing on the growth face of the seed substrate is greater than the maximum growing rate of silicon carbide crystal growing on the surface of the silicon carbide raw material. Therefore, a thick silicon carbide single crystal film can be obtained when silicon carbide single crystal having a diameter larger than 100 mm is grown.

Preferably in the step of growing silicon carbide single crystal in the method for manufacturing silicon carbide single crystal set forth above, the maximum height of the silicon carbide single crystal growing on the seed substrate exceeds 20 mm. Accordingly, silicon carbide single crystal having a maximum height exceeding 20 mm can be obtained.

Preferably in the step of growing silicon carbide single crystal in the method for manufacturing silicon carbide single crystal set forth above, the maximum height of the silicon carbide single crystal growing on the seed substrate exceeds 50 mm. Accordingly, silicon carbide single crystal having a maximum height exceeding 50 mm can be obtained.

Preferably in the step of growing silicon carbide single crystal in the method for manufacturing silicon carbide single crystal set forth above, sublimation of the silicon carbide raw material is carried out by heating a surface of the silicon carbide raw material at a region facing the center of the seed substrate by radiation. Accordingly, the temperature difference in the silicon carbide raw material can be reduced.

Preferably in the method for manufacturing silicon carbide single crystal set forth above, the step of preparing silicon carbide raw material includes the step of placing the silicon carbide raw material in a crucible. In the step of growing silicon carbide single crystal, sublimation of the silicon carbide raw material is carried out by heating the silicon carbide raw material through a hollow member provided protruding towards the silicon carbide raw material from an inner wall of the crucible at the side where the silicon carbide raw material is placed.

The method for manufacturing silicon carbide single crystal set forth above is carried out by heating the silicon carbide raw material through the hollow member. Accordingly, the temperature difference in the silicon carbide raw material can be reduced since the surface of the silicon carbide raw material around a central region can be heated efficiently by radiation.

Preferably in the method for manufacturing silicon carbide single crystal set forth above, the step of preparing silicon carbide raw material includes the step of placing the silicon carbide raw material in a crucible. In the step of growing silicon carbide single crystal, sublimation of the silicon carbide raw material is carried out by heating the silicon carbide raw material placed in a crucible having an inner diameter at the side where the silicon carbide raw material is arranged being larger than the inner diameter of the crucible at the side where the seed substrate is arranged.

Since the inner diameter of the crucible where the silicon carbide raw material is placed is larger, the height of the silicon carbide raw material can be reduced. Accordingly, the temperature distribution of the silicon carbide raw material can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram to describe the maximum growing rate of silicon carbide single crystal in a method for manufacturing silicon carbide single crystal according to a first embodiment.

FIG. 2 is a sectional view schematically representing a configuration of a manufacturing device for silicon carbide single crystal according to the first embodiment.

FIG. 3 is a sectional view schematically representing a configuration of a manufacturing device for silicon carbide single crystal according to a second embodiment.

FIG. 4 is a sectional view schematically representing a configuration of a modification of the manufacturing device for silicon carbide single crystal according to the second embodiment.

FIG. 5 is a flowchart to describe a method for manufacturing silicon carbide single crystal according to the first embodiment.

### DESCRIPTION OF THE PREFERRED EMBODIMENTS

Embodiments of the present invention will be described hereinafter based on the drawings. In the drawings, the same or corresponding elements have the same reference characters allotted, and description thereof will not be repeated.

As to the crystallographic notation in the present specification, a specific orientation is represented by [ ], a group of orientations is represented by < >, a specific plane is represented by ( ) and a group of equivalent planes is represented by { }. For a negative index, a bar (-) is typically allotted above a numerical value in the crystallographic aspect. However, in the present specification, a negative sign will be attached before the numerical value. Furthermore, the angle is defined based on a system in which the omnidirectional angle is 360°.

### First Embodiment

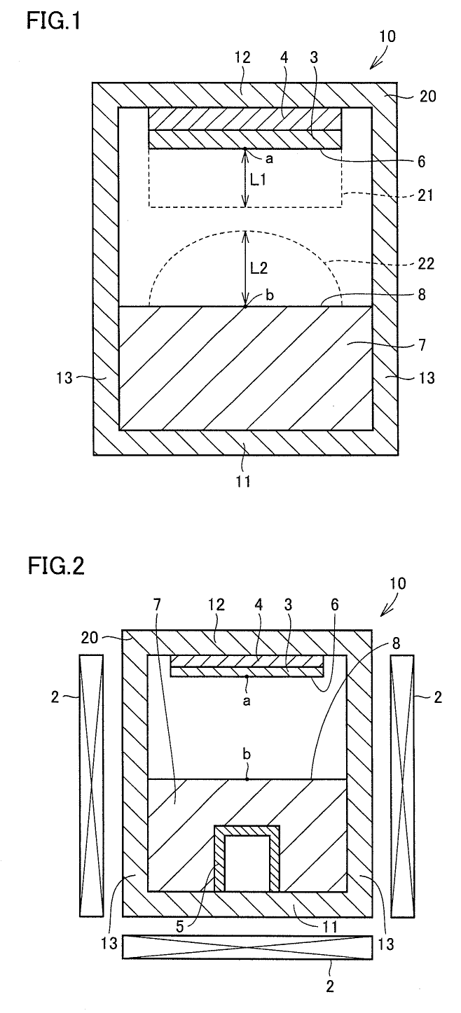

Referring to FIGS. 1 and 5, a method for manufacturing silicon carbide single crystal according to the present embodiment will be described. The method for manufacturing silicon carbide single crystal of the present embodiment is directed to manufacturing silicon carbide single crystal having a diameter larger than 100 mm by sublimation. The method mainly includes a seed substrate and silicon carbide raw material preparation step (FIG. 5: S10), and a silicon carbide single crystal growing step (FIG. 5: S20).

Referring to FIG. 1, the seed substrate and silicon carbide raw material preparation step (FIG. 5: S10) is carried out. Specifically, silicon carbide raw material 7 is placed in a crucible 20. A seed substrate 3 is arranged at a position facing silicon carbide raw material 7. Seed substrate 3 is held by a seed substrate holder 4. Seed substrate 3 is made of silicon carbide single crystal. A growth face 6 of seed substrate 3 is the {0001} plane, for example. Growth face 6 may be a plane inclined by an off angle within approximately 8°, for example, relative to the {0001} plane. Since the present embodiment corresponds to a method for manufacturing silicon carbide single crystal having a diameter larger than 100 mm, the diameter of seed substrate 3 is also larger than 100 mm.

Then, the silicon carbide single crystal growing step (FIG. 5: S20) is carried out. Specifically, by heating silicon carbide raw material 7 placed in crucible 20, silicon carbide raw material 7 is sublimated. The sublimated raw material gas recrystallizes on growth face 6 of seed substrate 3, whereby silicon carbide single crystal is grown on growth face 6.

In the step of growing silicon carbide single crystal, the maximum growing rate of the silicon carbide single crystal growing on growth face 6 of seed substrate 3 is greater than the maximum growing rate of the silicon carbide crystal growing on surface 8 of silicon carbide raw material 7. As used herein, the maximum growing rate is the value dividing the maximum value of the height of the silicon carbide single crystal grown divided by the growing time. Referring to FIG. 1, the value of a maximum height L1 of the silicon carbide single crystal growing on growth face 6 of seed substrate 3 divided by the time required for growing is the maximum growing rate of the silicon carbide single crystal growing on growth face 6 of seed substrate 3. In addition, silicon carbide crystal is growing on a surface 8 of silicon carbide raw material 7. The value of a maximum height L2 of the silicon carbide crystal grown on surface 8 of silicon carbide raw material 7 divided by the time required for growing is the maximum growing rate of the silicon carbide crystal growing on surface 8 of silicon carbide raw material 7.

Preferably in the step of growing silicon carbide single crystal, the maximum height of the silicon carbide single crystal growing on the seed substrate exceeds 20 mm. More preferably, the maximum height of the silicon carbide single crystal growing on the seed substrate exceeds 50 mm. Referring to FIG. 2, a manufacturing device for silicon carbide single crystal according to the present embodiment will be described.

A manufacturing device 10 for silicon carbide single crystal according to the present embodiment is directed to growing silicon carbide single crystal having a diameter larger than 100 mm by sublimation. Manufacturing device 10 mainly includes a crucible 20, a heater 2, and a hollow member 5.

Crucible 20 is made of carbon. Silicon carbide raw material 7 is placed in crucible 20. Seed substrate 3 is arranged at a position facing surface 8 of silicon carbide raw material 7. Seed substrate 3 is held by a seed substrate holder 4. Seed substrate holder 4 is held by a lid section 12 of crucible 20.

Around a sidewall 13 of crucible 20 is provided a heater 2 to heat silicon carbide raw material 7 placed in crucible 20. Heater 2 is arranged so as to also cover a bottom 11 of crucible 20. Preferably, heater 2 is arranged to cover the entire bottom 11 of crucible 20. Heater 2 may be an induction heating type heater, or a resistance heating type heater.

Hollow member 5 is empty inside. Hollow member 5 is provided to extend towards seed substrate 3 from bottom 11 of crucible 20 at the upper end face around the central region. Hollow member 5 is enclosed by silicon carbide raw material 7. Preferably, hollow member 5 is embedded in silicon carbide raw material 7. The height of hollow member 5 is lower than the height of silicon carbide raw material 7. Furthermore, heater 2 is located below hollow member 5. Since hollow member 5 is empty, the surface of silicon carbide raw material 7 around the central region can be heated efficiently by radiation. Thus, the temperature distribution of silicon carbide raw material 7 can be reduced. Alternatively, crucible 20 may have a bottom shaped protruding towards seed substrate 3 around the central region, instead of providing hollow member 5.

The thickness of bottom 11 of crucible 20 is preferably greater than 10 mm. More preferably, the thickness of bottom 11 of crucible 20 is greater than or equal to 20 mm. Accordingly, bottom 11 of crucible 20 can be heated efficiently by thermal conduction through carbon having thermal conductivity higher than that of silicon carbide.

Referring to FIGS. 2 and 5, a method for manufacturing silicon carbide single crystal according to the present embodiment will be described.

In the step of growing silicon carbide single crystal of the present embodiment, sublimation of silicon carbide raw material 7 is carried out by heating the surface of silicon carbide raw material 7 at a region facing the center “a” of seed substrate 3 by radiation. More specifically, in the seed substrate and silicon carbide raw material preparation step (FIG. 5: S10), seed substrate 3 is attached to seed substrate holder 4. Silicon carbide raw material 7 is placed in crucible 20. In the silicon carbide single crystal growing step (FIG. 5: S20), sublimation of silicon carbide raw material 7 is carried out by heating silicon carbide raw material 7 through hollow member 5. Hollow member 5 is provided to protrude into the silicon carbide raw material 7 side from the inner wall of crucible 20 at the side where silicon carbide raw material 7 is placed (that is, from bottom 11 of crucible 20).

The functional effect of the present embodiment will be described hereinafter.

If the size of silicon carbide single crystal to be grown becomes larger, the inner diameter of crucible 20 used must also be increased. If the inner diameter of crucible 20 is made larger, the distance from heater 2 arranged at the outer side of crucible 20 to the center “b” at surface 8 of silicon carbide raw material 7 (in other words, to the region of surface 8 of silicon carbide raw material 7 facing the center “a” of seed substrate 3) becomes longer. Therefore, the temperature distribution of silicon carbide raw material 7 will become greater since the region around the center “b” at surface 8 of silicon carbide raw material 7 is not readily heated.

If the temperature around the center “b” at surface 8 of silicon carbide raw material 7 becomes relatively low, the sublimated silicon carbide gas will be recrystallized on surface 8 of silicon carbide raw material 7. Therefore, silicon carbide crystal will also grow on surface 8 of silicon carbide raw material 7. If silicon carbide crystal grows on surface 8 of silicon carbide raw material 7, the space where silicon carbide single crystal can grow on growth face 6 of seed substrate 3 will become smaller, leading to difficulty in growing a thick silicon carbide single crystal film.

According to the method for manufacturing silicon carbide single crystal of the present embodiment, the maximum growing rate of silicon carbide single crystal growing on growth face 6 of seed substrate 3 is greater than the maximum growing rate of silicon carbide crystal growing on surface 8 of silicon carbide raw material 7. Therefore, when silicon carbide single crystal having a diameter larger than 100 mm is grown, a thick silicon carbide single crystal film can be obtained. Furthermore, the growing rate of silicon carbide single crystal growing on seed substrate 3 can be improved. Moreover, since growth of silicon carbide crystal on surface 8 of silicon carbide raw material 7 can be suppressed, the change in the growing environment of silicon carbide single crystal on seed substrate 3 can be reduced. Accordingly, occurrence of crystal defect at the silicon carbide single crystal can be reduced.

According to the method for manufacturing silicon carbide single crystal of the present embodiment, sublimation of silicon carbide raw material in the step of growing silicon carbide single crystal is carried out by heating surface 8 of silicon carbide raw material 7 at a region facing the center of seed substrate 3 through radiation. Accordingly, the temperature distribution of silicon carbide raw material 7 can be reduced. As a result, a thick silicon carbide single crystal film can be grown on seed substrate 3 by suppressing the growth of silicon carbide crystal on silicon carbide raw material 7.

The method for manufacturing silicon carbide single crystal of the present invention is carried out by heating the silicon carbide raw material through hollow member 5. Accordingly, surface 8 of silicon carbide raw material 7 around the central region can be heated more efficiently by radiation, allowing the temperature distribution of silicon carbide raw material 7 to be reduced. As a result, a thick silicon carbide single crystal film can be grown on seed substrate 3 by suppressing growth of silicon carbide crystal on silicon carbide raw material 7.

### Second Embodiment

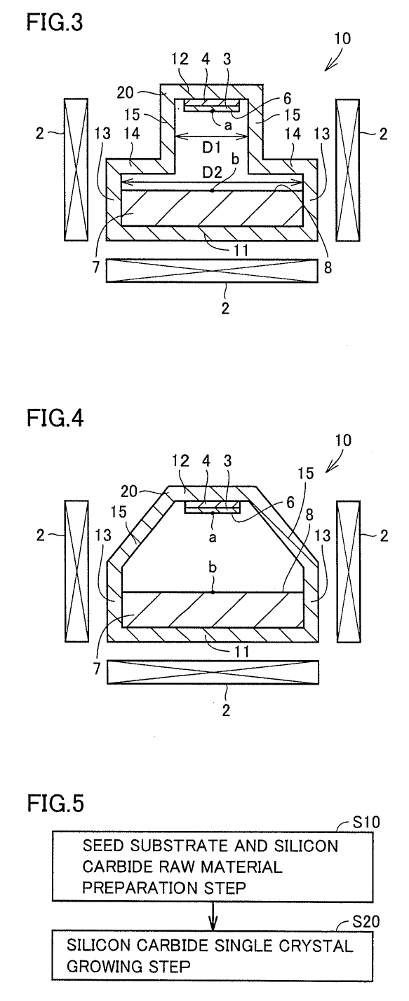

Referring to FIG. 3, a manufacturing device for silicon carbide single crystal according to the present embodiment will be described hereinafter. The manufacturing device for silicon carbide single crystal according to the second embodiment differs from the manufacturing device for silicon carbide single crystal according to the first embodiment in the shape of crucible 20 and the absence of hollow member 5. The remaining configuration is substantially similar to that of the manufacturing device of the first embodiment.

In crucible 20 of manufacturing device 10 for silicon carbide single crystal according to the present embodiment, the inner diameter D2 of crucible 20 where silicon carbide raw material 7 is placed is larger than the inner diameter D1 of crucible 20 at the side where seed substrate 3 is arranged. Further, heater 2 is arranged below crucible 20 to cover bottom 11 of crucible 20. Preferably, heater 2 is arranged to cover bottom 11 of crucible 20 entirely. By increasing inner diameter D2 of crucible 20 where silicon carbide raw material 7 is placed, the overall height of silicon carbide raw material 7 can be reduced. Accordingly, the temperature distribution of silicon carbide raw material 7 can be reduced.

A shoulder 14 is provided so as to connect a first sidewall 13 of crucible 20 at the side where silicon carbide raw material 7 is arranged and a second sidewall 15 of crucible 20 at the side where seed substrate 3 is arranged. Heater 2 is arranged to surround first sidewall 13 and second sidewall 15. In the present embodiment, the height of heater 2 is greater than the height of first sidewall 13. Accordingly, the heat generated by heater 2 can heat shoulder 14 of crucible 20 efficiently. Heated shoulder 14 extends from first sidewall 13 towards the region of center “b” at surface 8 of silicon carbide raw material 7. Accordingly, shoulder 14 can heat the region of center “b” at silicon carbide raw material 7 efficiently.

Referring to FIG. 4, an example of modification of manufacturing device 10 for silicon carbide single crystal according to the present embodiment will be described. As shown in FIG. 4, second sidewall 15 of crucible 20 at the side where seed substrate 3 is arranged may be tapered. In the present embodiment, the taper is provided such that the inner diameter of crucible 20 becomes larger from the side of seed substrate 3 towards silicon carbide raw material 7. Heater 2 is arranged to surround first sidewall 13 and second sidewall 15. Heater 2 is also arranged below bottom 11 of crucible 20 so as to cover bottom 11. Preferably, heater 2 is arranged to cover bottom 11 of crucible 20 entirely.

Second sidewall 15 of crucible 20 is inclined relative to first sidewall 13. The inner diameter of crucible 20 becomes smaller from the side of silicon carbide raw material 7 towards seed substrate 3. Accordingly, sublimation gas can be gathered efficiently towards seed substrate 3.

### EXAMPLE

Examples will be described hereinafter.

The examples are aimed to examine the maximum growing rate of the silicon carbide single crystal growing on growth face 6 of seed substrate 3 and the crystal thickness, as well as the maximum growing rate of the silicon carbide crystal growing on surface 8 of silicon carbide raw material 7 and the crystal thickness, employing the method for manufacturing silicon carbide single crystal described in the first embodiment and the method for manufacturing silicon carbide single crystal according to comparative examples.

For comparative examples, silicon carbide single crystal having a diameter of 2 inches, 3 inches, 4 inches, 5 inches, and 6 inches were manufactured. The comparative example is absent of hollow member 5. A crucible 20 having an inner diameter at the side where seed substrate 3 is arranged being identical to the inner diameter of crucible 20 at the side where silicon carbide raw material 7 is arranged was employed.

In the inventive example, silicon carbide single crystal having a diameter of 6 inches was manufactured. In Inventive Example 1, crucible 20 described in the first embodiment was employed. Specifically, crucible 20 employed in Inventive Example 1 includes hollow member 5. In Inventive Example 2, crucible 20 described in the second embodiment was employed. Specifically, crucible 20 employed in Inventive Example 2 has an inner diameter at the side where silicon carbide raw material 7 is arranged being larger than the inner diameter of crucible 20 at the side where seed substrate 3 is arranged.

The empirical results will be described with reference to Table 1.

TABLE 1

| | | | | | | Inventive | | Inventive | |
|---|---|---|---|---|---|---|---|---|---|
| | Comparative Example | | | | | Example 1 | | Example 2 | |
| Diameter (inch) | 2 | 3 | 4 | 5 | 6 | 6 | 6 | 6 | 6 |
| Growing rate on seed substrate | 0.3 | 0.3 | 0.2 | 0.1 | 0.05 | 0.3 | 0.25 | 0.3 | 0.25 |
| (mm/h) | | | | | | | | | |
| Crystal thickness on | 30 | 30 | 20 | 10 | 5 | 30 | 50 | 30 | 50 |
| seed substrate (mm) | | | | | | | | | |
| Growing rate on raw material | 0 | 0 | 0.2 | 0.3 | 0.5 | 0 | 0 | 0 | 0 |
| surface (mm/h) | | | | | | | | | |
| Height of recrystallization | 0 | 0 | 20 | 30 | 50 | 0 | 0 | 0 | 0 |
| on raw material surface (mm) | | | | | | | | | |
| Ratio of growing rate | 0 | 0 | 1 | 3 | 10 | 0 | 0 | 0 | 0 |

When silicon carbide single crystal having a diameter of 2 inches and 3 inches of the comparative examples was grown, the maximum growing rate on seed substrate 3 was both 0.3 mm/h, and the crystal thickness of the silicon carbide single crystal grown on seed substrate 3 was both 30 mm. Recrystallization of silicon carbide hardly occurred on silicon carbide raw material 7.

When silicon carbide single crystal having a diameter of 4 inches of the comparative example was grown, the maximum grown rate on seed substrate 3 was 0.2 mm/h, and the crystal thickness of the silicon carbide single crystal grown on seed substrate 3 was 20 mm. Further, the maximum growing rate on silicon carbide raw material 7 was 0.2 mm/h, and the recrystallization height of silicon carbide crystal on silicon carbide raw material 7 was 20 mm. The ratio of the growing rate which is the maximum growing rate on silicon carbide raw material 7 divided by the maximum growing rate on seed substrate 3 was 1.

When silicon carbide single crystal having a diameter of 5 inches and 6 inches (in other words, having a diameter larger than 100 mm) was grown in the comparative example, the maximum growing rate on seed substrate 3 was 0.1 mm/h and 0.05 mm/h, and the crystal thickness of the silicon carbide single crystal grown on seed substrate 3 was 10 mm and 5 mm, respectively. Further, the maximum growing rate on silicon carbide raw material 7 was 0.3 mm/h and 0.5 mm/h, and the recrystallization height of the silicon carbide crystal on silicon carbide raw material 7 was 30 mm and 50 mm, respectively. The ratio of the growing rate which is the maximum growing rate on silicon carbide raw material 7 divided by the maximum growing rate on seed substrate 3 was 3 and 10, respectively.

Thus, when silicon carbide single crystal was grown by the method of the comparative examples, it was confirmed that the crystal thickness of silicon carbide single crystal grown on seed substrate 3 becomes smaller as the diameter of the silicon carbide single crystal becomes larger. When silicon carbide single crystal having a diameter larger than 100 mm was manufactured by the method of the comparative example, silicon carbide single crystal having a crystal thickness exceeding 20 mm could not be grown on seed substrate 3.

In contrast, when silicon carbide single crystal having a diameter of 6 inches was grown using the manufacturing method of Inventive Example 1 and Inventive Example 2, silicon carbide single crystal having a crystal thickness greater than or equal to 30 mm could be grown on seed substrate 3. Specifically, when the maximum growing rate on seed substrate 3 was 0.3 mm/h, the crystal thickness of the silicon carbide single crystal grown on seed substrate 3 was 30 mm. Further, when the maximum growing rate on seed substrate 3 was 0.25 mm/h, the crystal thickness of the silicon carbide single crystal grown on seed substrate 3 was 50 mm. Recrystallization of silicon carbide hardly occurred on silicon carbide raw material 7.

Thus, it was proved that silicon carbide single crystal having a crystal thickness greater than or equal to 30 mm could be obtained on seed substrate 3 when silicon carbide single crystal was manufactured using the manufacturing method according to Inventive Example 1 and Inventive Example 2.

Although the present invention has been described and illustrated in detail, it is clearly understood that the same is by way of illustration and example only and is not to be taken by way of limitation, the scope of the present invention being interpreted by the teams of the appended claims.

What is claimed is:

1. A method for manufacturing silicon carbide single crystal having a diameter larger than 100 mm by sublimation, said method comprising the steps of:
preparing a seed substrate made of silicon carbide and silicon carbide raw material, and
growing said silicon carbide single crystal on a growth face of said seed substrate by sublimating said silicon carbide raw material,
in said step of growing said silicon carbide single crystal, a maximum growing rate of said silicon carbide single crystal growing on said growth face of said seed substrate being greater than a maximum growing rate of silicon carbide crystal growing on a surface of said silicon carbide raw material.

2. The method for manufacturing silicon carbide single crystal according to claim 1, wherein a maximum height of said silicon carbide single crystal growing on said seed substrate exceeds 20 mm in said step of growing said silicon carbide single crystal.

3. The method for manufacturing silicon carbide single crystal according to claim 1, wherein a maximum height of said silicon carbide single crystal growing on said seed substrate exceeds 50 mm in said step of growing said silicon carbide single crystal.

4. The method for manufacturing silicon carbide single crystal according to claim 1, wherein sublimation of said silicon carbide raw material is carried out by heating said surface of said silicon carbide raw material at a region facing the center of said seed substrate by radiation, in said step of growing said silicon carbide single crystal.

5. The method for manufacturing silicon carbide single crystal according to claim 1, wherein
said step of preparing silicon carbide raw material includes the step of placing said silicon carbide raw material in a crucible,
sublimation of said silicon carbide raw material is carried out by heating said silicon carbide raw material through a hollow member provided protruding towards said silicon carbide raw material from an inner wall of said crucible at a side where said silicon carbide raw material is placed, in said step of growing said silicon carbide single crystal.

6. The method for manufacturing silicon carbide single crystal according to claim 1, wherein
said step of preparing silicon carbide raw material includes the step of placing said silicon carbide raw material in a crucible,
sublimation of said silicon carbide raw material is carried out by heating said silicon carbide raw material placed in said crucible having an inner diameter at a side where said silicon carbide raw material is arranged being larger than the inner diameter of said crucible at the side where said seed substrate is arranged, in said step of growing said silicon carbide single crystal.
